(19) United States
(12) Patent Application Publication
(10) Pub. No.: US 2024/0304261 A1
(43) Pub. Date: Sep. 12, 2024

(54) SELF-CORRECTED THRESHOLD VOLTAGES IN NON-VOLATILE MEMORY

(71) Applicant: International Business Machines Corporation, Armonk, NY (US)

(72) Inventors: Krishna Thangaraj, San Jose, CA (US); Eric Raymond Evarts, Niskayuna, NY (US)

(21) Appl. No.: 18/179,478

(22) Filed: Mar. 7, 2023

(51) Int. Cl. G11C 16/34

(52) U.S. Cl. CPC G11C 16/3404

(57) ABSTRACT

Embodiments disclosed herein include a semiconductor structure. The semiconductor structure may include a flash controller and a first flash chip communicably coupled with the flash controller. The first flash chip may include a first flash cell array and a first voltage recalibration analog circuit (VRAC) configured to adjust a first threshold voltage for the first flash cell array based on a tracking of accesses to the first flash cell array.

### BACKGROUND

The present invention relates generally to operating flash memory chips, and more particularly to using a voltage recalibration analog circuit (VRAC) within each flash chip.

Flash memory devices store data using an electrical charge to determine whether each cell is a “0” or a “1.” Billions of these flash memory cells store terabytes of information on silicon substrate chips. In the earliest designs for flash memory, each cell was designed to store a single bit of digital information and was called single-level cell technology (SLC). Later designs have taken advantage of the possibility for a cell to store more than one state. That is, cells within a multiple-level cell (MLC) flash device use a range of voltages to store two-bits, three-bits, four-bits, or more worth of binary information.

Flash memory is programmed and erased by applying a voltage that sends electrons through an insulator. The location of electrons within the cell determines when current will flow between a source and a sink. Current flowing through the cell represents a “1” value for the cell, while current not flowing represents a “0” value for the cell. When writing and erasing NAND, the flash memory cell sends electrons through the insulator and back, and the insulator can wear out and deteriorate over time. The exact number of these cycles that the NAND takes to wear down in each individual cell varies by the design of the flash memory. After a certain amount of cycles, the memory cell changes in the amount of voltage that is takes to change or enable the electrons to flow through. This voltage is known as the threshold voltage.

### SUMMARY

Embodiments of the present invention include a semiconductor structure. The semiconductor structure may include a flash controller and a first flash chip communicably coupled with the flash controller. The first flash chip may include a first flash cell array and a first voltage recalibration analog circuit (VRAC) configured to adjust a first threshold voltage for the first flash cell array based on a tracking of accesses to the first flash cell array. The VRAC provides the benefit of extra processing time for the flash controller by removing the need for the flash controller to monitor and adjust the threshold voltage as cells in the first flash cell array change over time. This benefit comes at the cost of extra components in the first flash chip, but the overall improvement of the flash controller and the semiconductor structure as a whole can be worth this cost.

Certain embodiments may include a VRAC that has analog storage elements incorporated internally to non-volatile memory of the flash chip. These analog storage elements may include a static table and a dynamic table. The static and dynamic table provide the benefit of storing the appropriate threshold voltages for the number of accesses that have occurred for each cell or cell block. Analog storage is compact and non-volatile, and thus benefits the VRAC to be able to adjust the threshold voltage efficiently and quickly. The dynamic table, in certain embodiments, may include metadata representative of the encoded aggregate of the accesses, the static table may include metadata representative of set voltage threshold offsets for the first flash cell array that are a function selected from the group consisting of: temperature, program erase cycle count, and retention requirements. Furthermore, the analog storage elements may be connected to the command address bus of the non-volatile memory.

Embodiments of the present invention include a method of operating a semiconductor structure. The method may include monitoring accesses to a first flash cell array within a first flash chip physically separated from and communicably coupled with the flash controller, comparing dynamic metadata states representative of the encoded aggregate of the accesses to static metadata representative of set voltage threshold offsets for the flash cell array, and updating a first threshold voltage for the first flash cell array based on the comparison of the dynamic metadata and static metadata. Monitoring accesses from within the first flash chip enables the flash controller to devote more processing resources to other tasks by removing the need for the flash controller to monitor and adjust the threshold voltage as cells in the first flash cell array. This benefit comes at the cost of extra components (i.e., a voltage recalibration analog circuit (VRAC) performing the monitoring, comparing, and updating steps) in the first flash chip, but the overall improvement of the flash controller and the semiconductor structure as a whole can be worth this cost.

Embodiments of the present invention include a semiconductor structure that has a flash controller, and a first flash chip physically separated from and communicably coupled with the flash controller. The first flash chip may include a first flash cell array and a first voltage recalibration analog circuit (VRAC) with analog storage elements incorporated internally to non-volatile memory of the flash chip, wherein the first VRAC compares the analog storage elements to adjust a first threshold voltage for the first flash cell array. The VRAC provides the benefit of extra processing time for the flash controller by removing the need for the flash controller to monitor and adjust the threshold voltage as cells in the first flash cell array change over time. This benefit comes at the cost of extra components in the first flash chip, but the overall improvement of the flash controller and the semiconductor structure as a whole can be worth this cost.

A more complete understanding of the present invention, as well as further features and advantages of the present invention, will be obtained by reference to the following detailed description and drawings.

### BRIEF DESCRIPTION OF THE DRAWINGS

FIG. 1 depicts a functional block diagram illustrating a memory storage environment, in accordance with one embodiment of the present invention.

FIG. 2 depicts functional block diagram illustrating a memory storage environment, in accordance with one embodiment of the present invention.

FIG. 3 depicts a functional block diagram illustrating a voltage recalibration analog circuit (VRAC), in accordance with one embodiment of the present invention.

FIG. 4 depicts a table illustrating storage of metadata within a static table of a voltage recalibration analog circuit, in accordance with one embodiment of the present invention.

FIG. 5 depicts a table illustrating storage of metadata within a dynamic table of a voltage recalibration analog circuit, in accordance with one embodiment of the present invention.

FIG. 6 depicts functional block diagram illustrating a memory storage environment, in accordance with one embodiment of the present invention.

### DETAILED DESCRIPTION

In the following detailed description, reference is made to the accompanying drawings, which show specific examples of embodiments of the invention. These embodiments are described in sufficient detail to enable those skilled in the art to practice them, and it is to be understood that other embodiments may be utilized, and that structural, logical, and electrical changes may be made without departing from the described embodiments. The following detailed description is, therefore, not to be taken in a limiting sense, and the included embodiments are defined by the appended claims.

In the following description, numerous specific details are set forth, such as particular structures, components, materials, dimensions, processing steps and techniques, in order to provide an understanding of the various embodiments of the present application. However, it will be appreciated by one of ordinary skill in the art that the various embodiments of the present application may be practiced without these specific details. In other instances, well-known structures or processing steps have not been described in detail in order to avoid obscuring the present application.

References in the specification to “one embodiment,” “an embodiment,” “certain embodiments,” etc., indicate that the embodiment described may include a particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “right,” “left,” “vertical,” “horizontal,” “top,” “bottom,” and derivatives thereof shall relate to the disclosed structures and methods, as oriented in the drawing Figures. The terms “above,” “below,” “positioned on,” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “beneath” or “under” another element, it can be directly beneath or under the other element, or intervening elements may be present. In contrast, when an element is referred to as being “directly beneath” or “directly under” another element, there are no intervening elements present. A first component is communicably coupled with a second component when the first component is permanently attached to the second component, or when both components are attached within a mutual structure in a way that enables electronic communication between the two components. Each reference number may refer to an item individually or collectively as a group. For example, die 102 may refer to a single die 102 or multiple dies 102.

Provided herein are semiconductor structures that store voltage offset information within the flash cell chips, and then internally change the offset for individual memory cells when conditions are met for that change. A static table may store the conditions for changing the voltage offset, while a dynamic table may store the updating actual operating conditions. For example, the dynamic table may store the number of times that each particular cell is written to, while the static table stores the voltage thresholds for each cell mapped with the number of times the cell has been written to.

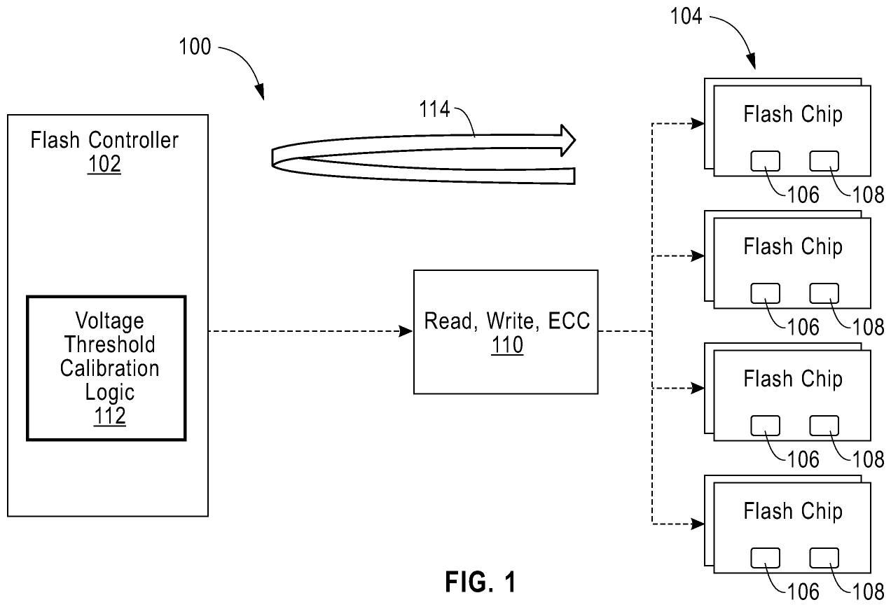

Turning now to the figures, FIG. 1 depicts a functional block diagram illustrating a memory storage environment 100, in accordance with one embodiment of the present invention. FIG. 1 provides only an illustration of one implementation and does not imply any limitations regarding the environments in which different embodiments may be implemented. Many modifications to the depicted environment may be made by those skilled in the art without departing from the scope of the invention as recited by the claims.

The memory storage environment 100 includes a flash controller 102 and a plurality of flash chips 104. The flash controller 102 and the flash chips 104 may be attached within a device, or on the same circuit board that utilizes the memory storage environment 100 to store instructions or data for a host device. The host device can be a standalone computing device, a management server, a web server, a mobile computing device, or any other electronic device or computing system capable of receiving, sending, and processing data. In other embodiments, the host device can represent a server computing system utilizing multiple computers as a server system, such as in a cloud computing environment. In another embodiment, the host device can be a laptop computer, a tablet computer, a netbook computer, a personal computer (PC), a desktop computer, a personal digital assistant (PDA), a smart phone, or any programmable electronic device capable of communicating with other computing devices to access the memory storage environment 100.

The flash controller 102 manages the data flow between the host device and the flash chips 104. When data is written to the flash chips 104, the flash controller 102 organizes it into blocks of data and writes those blocks of data to the appropriate pages of the memory. When the data/data blocks are read from the memory, the flash controller 102 retrieves the data from the appropriate pages and sends the data to the host device. The flash controller 102 may send the data to a flash control logic 106 within each of the flash chips in the plurality of flash chips 104. The flash control logic 106 may then in turn send the data to specific cells within a flash cell array 108. The flash control logic 106 is a type of logic circuitry that controls the process of programming and erasing the cells of the flash cell array 108. The flash control logic receives commands 110 from the flash controller 102, to read and write data. In addition, the flash controller 102 may send commands 110 that manage error correction codes (ECC), which help to ensure the accuracy of the data being read from the memory. ECC involves adding extra bits of data to the stored data that can be used to detect and correct errors that may occur during the read process.

The flash control logic 106 translates the commands 110 into electrical signals that control the flow of current in the flash memory cells of the flash cell arrays 108. The flash control logic 106 thus controls the voltages of the signals for programming and erasing of memory cells, and the wear leveling process. Wear leveling evenly distributes writes across the whole flash cell array 108 to prevent premature wear and failure of the flash chips 104. Overall, the flash control logic 106 ensures data integrity, longevity, and reliable performance.

To control the erasing of the memory cells, the flash control logic 106 sends (e.g., when the flash controller 102 sends an erase command 110) electrical signals to the specific memory cells in the flash cell array 108 that are to be erased. The electrical signals reset the stored values in the specific memory cells to a blank state. Similarly, when the flash controller 102 sends a write command, the flash control logic 106 sends electrical signals to the specific memory cells in the flash cell array 108 that are to be programmed with the new data. The flash control logic 106 may then check to ensure that the programming was successful by reading back the data and comparing it to the original data.

The electrical signals that the flash control logic 106 uses are, in general, a specific voltage (called a “threshold voltage”) tailored to the memory cells in the flash cell array 108. The threshold voltage of a flash memory cell is the voltage at which the cell switches between its two logic states. The ability to control the threshold voltage of a flash memory cell is important for several reasons. Firstly, it allows for the reliable storage and retrieval of data. If the threshold voltage is not well-controlled, it may lead to errors in reading or writing data. This is especially important in multiple-level cell (MLC) devices that utilize ranges of voltages to store the digital information. For multi-bit flash cells (i.e., with higher the bits per cell), the number of voltage levels to be decoded within a cell is higher and consequently the margin between the adjacent levels is lower. Lower margins between adjacent levels have a larger potential of level crossing, which leads to bit errors. This is further exacerbated by progressive program/erase cycling of flash cells, and by data retention and read-disturb. These operations cause shifts and broadening of the threshold voltage distributions, leading to rapid deterioration of the raw bit-error rate (RBER) in the flash cell arrays 108. Secondly, it allows for improved endurance and longevity of the flash memory device. By sending signals in accordance with an accurate threshold voltage, the memory cells in the flash cell array 108 can be programmed and erased repeatedly without significant degradation of performance or loss of data.

One problem, however, that the flash control logic 106 may run into is that the threshold voltage for the memory cells changes through the lifecycle of the flash cell array 108. For instance, after several (hundreds, thousands) write cycles, the threshold voltage may increase or decrease for a certain cell, or even specific bits of information within the specific cells. In certain embodiments, therefore, the flash controller 102 may include a voltage threshold calibration logic (VTCL) 112 to keep up with these changes in the individual cells of the flash cell array 108. The VTCL 112 uses a monitoring process (represented by arrow 114) that queries the flash chips 104, and then responds to changes in the cells and adjusts the threshold voltages accordingly. The flash controller 102 may also employ methods to periodically adjust the read voltages in order to improve the RBER as the blocks undergo different types of stress. To do so, the flash controller 102 sends a signal to each flash control logic 106 and instruct the flash control logic 106 to adjust the threshold voltage. This process of monitoring and instructing all of the flash control logics 106 can use up valuable processing resources of the flash controller 102. Although read voltage calibration is effective in combating different types of the memory device stress, it requires a high volume of metadata to be kept by the controller (for each flash chip 104). This problem has become worse with MLC, as there are more voltages to calibrate and thus exponentially more metadata to track for each flash chip 104.

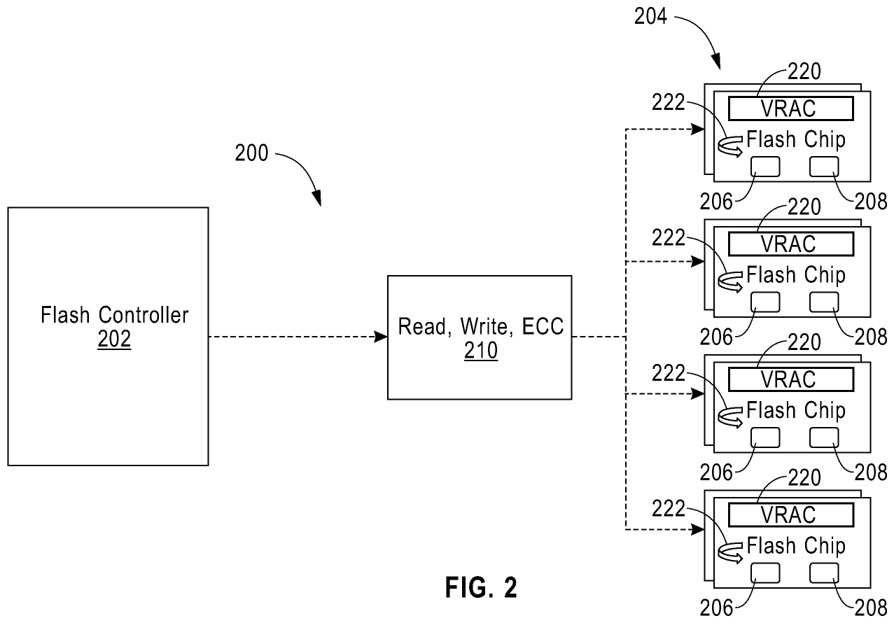

FIG. 2 depicts a schematic diagram illustrating a memory storage environment 200, in accordance with one embodiment of the present invention. The memory storage environment 200 includes a flash controller 202 and flash chips 204 as in the memory storage environment 200 described above.

The flash controller 202 manages the data flow between the host device and the flash chips 204. Again, as with the flash controller 102 described above, when data is written to the flash chips 204 the flash controller 202 organizes the data into blocks of data and writes the data to the appropriate pages of the memory. When data is read from the memory, the flash controller 202 retrieves the data from the appropriate flash chips 204 and sends the data to the host device. The flash controller 202 may send the data to a flash control logic 206 within each of the flash chips in the plurality of flash chips 204. The flash control logic 206 may then in turn send the data to specific cells within a flash cell array 208.

In the embodiment of FIG. 2, however, the flash controller 206 does not contain the VTCL 112. Rather, the function of monitoring the threshold voltage is assigned to voltage recalibration analog circuits (VRAC) 220 that are fabricated within each flash chip 204. The VRACs 220 within the flash chips 204 perform the same threshold voltage monitoring that was done by the VTCL 112 described above, but only for the flash chip 204 on which the VRAC 220 is fabricated. The flash controller 206, therefore, is more readily available to give read, write, and ECC commands 210 without having additional tasks of checking with the flash control logic 206 to change the threshold voltages.

The VRACs 220 is implemented within the flash chips 204 themselves and use a monitoring process (indicated by arrows 222) whereby the use and/or operation of the flash cell arrays 208 is recorded, and the VRACs 220 can change the threshold voltage according to the feedback that is received. For example, the VRACs 220 may measure a response to the current threshold voltage, and actively determine a likelihood that the cell will improperly activate/mis-activate. In other embodiments, the VRACs 220 may record a number of times that a cell in the flash cell arrays 208 is accessed or written to, and change the operating threshold voltage based on a stored value correlated with that number of times.

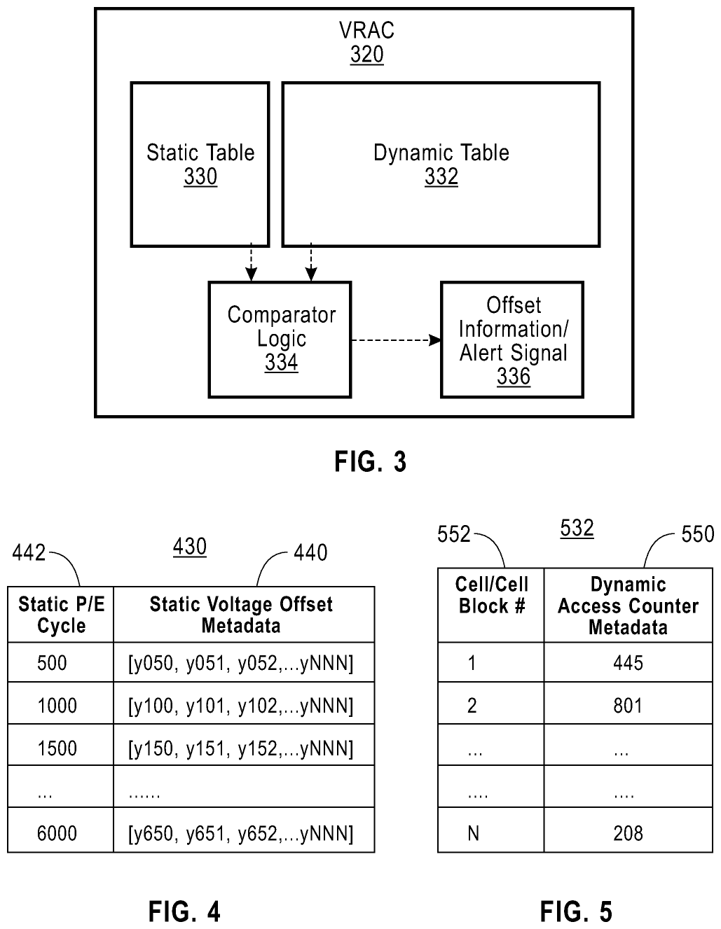

FIG. 3 depicts a functional block diagram illustrating a voltage recalibration analog circuit (VRAC) 320, in accordance with one embodiment of the present invention. The VRAC 320 controls the threshold voltage that is used to write to a flash cell array as described above. The threshold voltage in this embodiment, and subsequent changes to the threshold voltage, are governed by data contained in a static table 330 and a dynamic table 332. The static table and the dynamic table 332 may be fabricated in the flash chip (e.g., flash chip 204) as analog memory. The metadata used to control the voltage threshold recalibration for each flash chip is thus integrated into the flash chip directly. This direct storage enables each the VRAC 320 to perform the recalibration without the flash controller (e.g., flash controller 102, 202) having to store/manage and manipulate the meta-data, which saves overhead resources of the flash controller. Also, given the inbuilt compressibility of the analog storage medium, the footprint of the overall meta-data is dramatically reduced, and the flash chip can choose to employ a voltage recalibration algorithm that is more precise than algorithms using digital metadata storage on the flash controller due to the requirement of digital algorithms to group multiple pages to save metadata overhead.

FIG. 4 depicts a table illustrating storage of metadata within a static table 430 of a VRAC, in accordance with one embodiment of the present invention. The static table 430 records a static voltage offset metadata 440 for thresholds of program/erase (P/E) cycles 442. The static voltage offset metadata 440, in certain embodiments, is established during fabrication and may be based on historic performance or average performance for memory cells fabricated in a similar manner to the cells in the accompanying flash chip. For example, the static voltage offset metadata 440 may include metadata representative of set voltage threshold offsets for the flash cell array that are a function such as temperature, program erase cycle count, or retention requirements. The static voltage offset metadata 440 may be stored for varying numbers of cycles and varying groups of cells within a flash cell array. In the embodiment illustrated in FIG. 4, the static table 430 changes metadata instructions every 500 P/E cycles. That is, at 500 P/E cycles, the static table 430 includes threshold voltages for groups y050 through yNNN, and the threshold voltage would not change for any of those cell's groups until the cell crosses 1000 P/E cycles. At 1000 P/E cycles, the VRAC (e.g., VRAC 320) switches the threshold voltage to the second box of the static voltage offset metadata 440, and applies the voltage stored as y100 through yNNN.

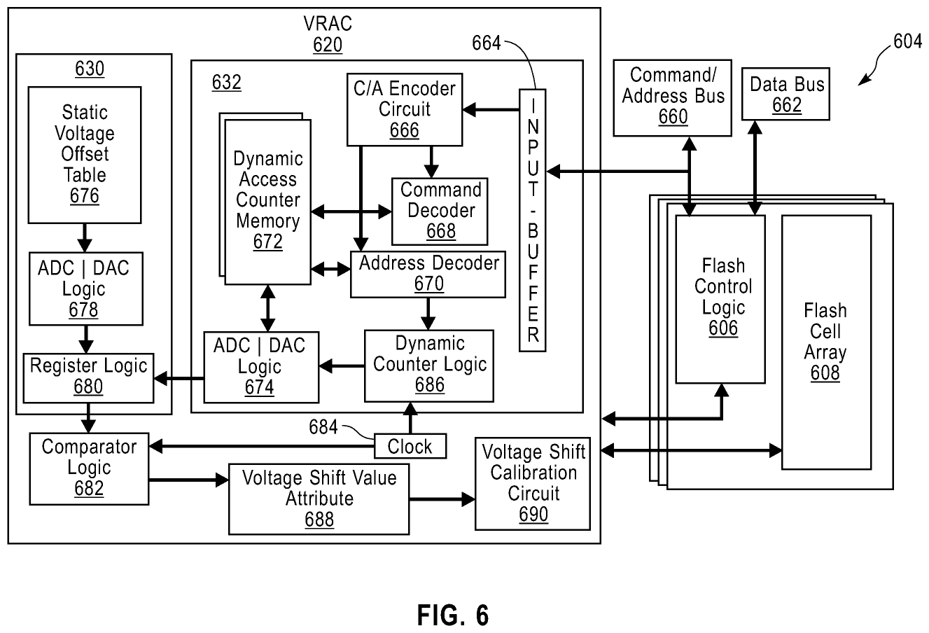

FIG. 5 depicts a table illustrating storage of metadata within a dynamic table 532 of a VRAC, in accordance with one embodiment of the present invention. The dynamic table 532 tracks dynamic access counter metadata 550 for each cell or block of cells 552 in the flash cell array of the flash chips. For example, in the illustrated embodiment, cell/cell block #1 has a dynamic access counter metadata of “445.” This means that the cell/cell block labeled #1 has, over the life of the flash chip, been programmed or erased 445 times. Similarly, cell/cell block #2 has a dynamic access counter metadata of “801.” This means that the cell/cell block labeled #2 has, over the life of the flash chip, been programmed or erased 801 times. The Nth cell/cell block has been programmed or erased 208 times, according to the dynamic table 532. With the static table 430 of FIG. 4 and the dynamic table 532 of FIG. 5, the VRAC 320 of FIG. 3, for example, could change the voltage threshold of cell/cell block #2 from the original factory-set voltage to the new threshold voltage indicated by the corresponding box in the static voltage offset metadata 440. The process for monitoring and updating the metadata may be made even more clear by describing the monitoring components illustrated in FIG. 6.

FIG. 6 depicts functional block diagram illustrating a flash chip 604, in accordance with one embodiment of the present invention. The flash chip 604 may be one of many flash chips, for example, that operate within a memory storage environment such as the memory storage environment 200 of FIG. 2. The flash chip 604 includes a flash cell array 608 that includes the cells/cell blocks of the flash chip 604, and a control logic 606 that executes access to the cells/cell block based on commands sent from a flash controller. The flash control logic 606 and the flash cell array 608 may communicated with a host device through a command/address bus 660 and a data bus 662, which send signals according to known processes to write and read data stored in the flash cell array 608.

The flash chip 604 also includes a VRAC 620 for controlling and adjusting the threshold voltages used by the flash control logic 606 to program or erase data to the flash cell array 608. The VRAC 620 is fabricated as part of the flash chip 604, for example on the same silicon substrate as the flash control logic 606 and the flash cell array 608. Each flash chip 604 may include an incorporated VRAC on the substrate. The VRAC 620 operates using a static table 630 and a dynamic table 632 with components for writing and accessing data in analog memory storage. The VRAC 620 monitors accesses to the flash cell array 608 within the flash chip 604 physically separated from and communicably coupled with the flash controller by communicating with the flash control logic 606, but may also receive signals indicative of the accesses to each cell/cell block in the flash cell array 608 directly from the command/address bus 660 to an input buffer 664 within the dynamic table 632. The input buffer 664 buffers the input signal from the command/address bus 660 for times when the input signal is running faster than the dynamic table 632 can operate.

The input buffer 664 sends signals of the accesses to a C/A encoder circuit 666 to convert the command/address bus signal into the separate command (such as read or write) and address (such as cell, block, page, etc.) portions of the signal . . . . The C/A encoder circuit 666 sends signals to each of a command decoder 668 and an address decoder 670 that update a dynamic access counter memory 672 with metadata representative of the encoded aggregate of the accesses to identify the conditions that a specific cell/cell block has been subjected to (e.g., programmed or erased). As mentioned above, the dynamic table 632 may utilize analog memory within the dynamic access counter memory 672 to track the conditions for each cell/cell block in the flash cell array 608. The analog memory of the dynamic access counter memory 672 may include SRAM, PCM, ReRam, STT-MRAM, or other types of analog memory. The dynamic table 632 includes an analog/digital converter 674 to read the data from the analog memory in the dynamic access counter memory 672 and convey the signal to the static table 630. Basically, the raw signal on the command/address bus needs to encode both an address and an action. The C/A encoder circuit 666 reads the raw signal, converts it to the command and address portions separately. The command decoder 668 then determines which type of signal is received and what action to take (for example, some particular memory may only increment the counter for writes while other particular memories could increment on both reads and writes, it would be technology specific). The address decoder 670 determines which address in the dynamic array needs to be updated.

The static table 630 also includes analog memory, labeled a static voltage offset table 676 in FIG. 6. The static voltage offset table 674 also utilizes an analog/digital converter 678 within the static table 630 that enables digital data to be written to, and read from, the static voltage offset table 674. The converted (digital) signals from the analog/digital converters 674, 678 are received by a register logic 680 within the static table 630 and then sent to a comparator logic 682 within the VRAC 620. The VRAC 620 and the comparator logic 682 compare dynamic metadata states representative of the encoded aggregate of the accesses to static metadata representative of set voltage threshold offsets for the flash cell array. This comparison determines if the conditions are met for changing or adjusting the threshold voltage.

The comparator logic 682 is alerted to calibration by a clock 684 that also send timing signals to a dynamic counter logic 686 within the dynamic table 632. When the comparator logic 682 determines that the conditions are met for an adjusted threshold voltage, the comparator logic 682 sends a voltage shift value attribute 688 to a voltage shift calibration circuit 690 that alerts the flash control logic 606, updating a first threshold voltage for the first flash cell array based on the comparison of the dynamic and static metadata. The flash control logic 606 then operates using the new voltage, as adjusted by the voltage shift value attribute 688.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor structure, comprising:
a flash controller; and
a first flash chip communicably coupled with the flash controller, comprising:
a first flash cell array; and
a first voltage recalibration analog circuit (VRAC) configured to adjust a first threshold voltage for the first flash cell array based on a tracking of accesses to the first flash cell array.

2. The semiconductor structure of claim 1, wherein the first VRAC comprises analog storage elements incorporated internally to non-volatile memory of the flash chip.

3. The semiconductor structure of claim 2, wherein the analog storage elements comprise a static table and a dynamic table.

4. The semiconductor structure of claim 3, wherein the dynamic table comprises metadata representative of the encoded aggregate of the accesses.

5. The semiconductor structure of claim 3, wherein the static table comprises metadata representative of set voltage threshold offsets for the first flash cell array that are a function selected from the group consisting of: temperature, program erase cycle count, and retention requirements.

6. The semiconductor structure of claim 2, wherein the analog storage elements are connected to the command address bus of the non-volatile memory.

7. The semiconductor structure of claim 1, further comprising a second flash chip, comprising:
a second flash cell array; and
a second VRAC configured to adjust a second threshold voltage for the second flash cell array based on a tracking of accesses to the second flash cell array.

8. The semiconductor structure of claim 1, wherein the first VRAC comprises a comparator logic.

9. A method, comprising:
monitoring accesses to a first flash cell array within a first flash chip physically separated from and communicably coupled with the flash controller;
comparing dynamic metadata states representative of the encoded aggregate of the accesses to static metadata representative of set voltage threshold offsets for the flash cell array; and
updating a first threshold voltage for the first flash cell array based on the comparison of the dynamic metadata and static metadata.

10. The method of claim 9, further comprising maintaining the dynamic metadata and static metadata in an analog non-volatile memory on the first flash chip.

11. The method of claim 10, further comprising using a flash controller to perform an action selected from the group consisting of: scrubbing the analog non-volatile memory, calibrating the analog non-volatile memory, erasing the analog non-volatile memory, and updating the analog non-volatile memory.

12. The method of claim 10, further comprising alerting the flash controller to take subsequent actions in the target regions of the non-volatile memory.

13. The method of claim 9, wherein comparing the dynamic metadata states to static metadata states comprises a periodic comparing.

14. The method of claim 9, wherein monitoring accesses to the first flash cell array comprises monitoring CA Bus commands sent to the flash control logic.

15. A semiconductor structure, comprising:
a flash controller; and
a first flash chip physically separated from and communicably coupled with the flash controller, comprising:
a first flash cell array; and
a first voltage recalibration analog circuit (VRAC) comprising analog storage elements incorporated internally to non-volatile memory of the flash chip, wherein the first VRAC compares the analog storage elements to adjust a first threshold voltage for the first flash cell array.

16. The semiconductor structure of claim 15, wherein the analog storage elements comprise a static table and a dynamic table.

17. The semiconductor structure of claim 16, wherein the dynamic table comprises metadata representative of the encoded aggregate of the accesses.

18. The semiconductor structure of claim 16, wherein the static table comprises metadata representative of set voltage threshold offsets for the first flash cell array that are a function selected from the group consisting of: temperature, program erase cycle count, and retention requirements.

19. The semiconductor structure of claim 18, further comprising a second flash chip, comprising:
a second flash cell array; and
a second VRAC comprising analog storage elements incorporated internally to non-volatile memory of the flash chip, wherein the first VRAC compares the analog storage elements to adjust a first threshold voltage for the first flash cell array.

20. The semiconductor structure of claim 18, wherein the first VRAC comprises a comparator logic.
